(19) United States
(12) Patent Application Publication
(10) Pub. No.: US 2007/0120176 A1
(43) Pub. Date: May 31, 2007

(54) EEPROM

(75) Inventor: Kouji Tanaka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/604,208

(22) Filed: Nov. 27, 2006

(30) Foreign Application Priority Data
Nov. 28, 2005 (JP) 2005-342079

(51) Int. Cl. H01L 29/788

(52) U.S. Cl. 257/316

(57) ABSTRACT

An EEPROM having a nonvolatile memory cell is provided. The nonvolatile memory cell has: a first well formed in a substrate; a floating gate formed on the substrate through a gate insulating film to overlap a first region of the first well; and first and second diffusion layers formed in the first well to contact the first region. A charge supply to the floating gate is performed through the gate insulating film between the first region and the floating gate. The first diffusion layer and the second diffusion layer are of opposite conductivity types and are provided such that efficiencies of the charge supply to the floating gate from respective of the first diffusion layer and the second diffusion layer are equal to each other.

### BACKGROUND OF THE INVENTION

1. Field of the Invention

The present invention relates to a nonvolatile memory, and particularly relates to an EEPROM (Electrically Erasable and Programmable Read Only Memory).

2. Description of the Related Art

An EEPROM is known as a nonvolatile memory capable of electrically programming and erasing data. A “single poly EEPROM” is a type of the EEPROM, which does not have a stacked gate but a single-layer gate. Such a single poly EEPROM is disclosed, for example, in the following patent documents.

An EEPROM described in Japanese Laid-Open Patent Application JP-H06-334190 has: an NMOS transistor formed on a P-type substrate; a PMOS transistor formed on an N-well in the P-type substrate; and a single-layer polysilicon (floating gate) formed on the P-type substrate through a gate insulating film. The single-layer polysilicon is not only a gate electrode of the NMOS transistor but also a gate electrode of the PMOS transistor. The N-well on which the PMOS transistor is formed serves as a control gate. Charges are injected into or ejected from the floating gate through the gate insulating film of the NMOS transistor.

In an EEPROM described in Japanese Laid-Open Patent Application JP-P2000-340773, an N+ diffusion layer formed in a surface portion of a semiconductor substrate functions as a control gate. The N+ diffusion layer overlaps a single-layer gate (floating gate) formed on the semiconductor substrate. The single-layer gate also overlaps a tunnel region in the semiconductor substrate, and charges are injected into the single-layer gate from the tunnel region. Furthermore, the EEPROM has a MOS transistor that uses the single-layer gate as a gate electrode. The above-mentioned tunnel region is a part of a source or a drain of the MOS transistor.

An EEPROM described in Japanese Laid-Open Patent Application JP-P2001-185633 has: a first N-well and a second N-well which are formed in a substrate; a single-layer gate (floating gate) formed on the substrate; and a read transistor. The first N-well and the single-layer gate overlap each other through a gate insulating film to form a first capacitor. The second N-well and the single-layer gate overlap each other through a gate insulating film to form a second capacitor. A P-type diffusion layer and an N-type diffusion layer are formed in each of the first and the second N-wells. The P-type diffusion layer is formed around the single-layer gate, while the N-type diffusion layer is formed away from the single-layer gate. Charges are injected into the single-layer gate through the gate insulating film at the first capacitor or the second capacitor.

An EEPROM described in U.S. Pat. No. 6,788,574 is illustrated in FIG. 1. In FIG. 1, a single-layer polygate 354 (floating gate 360) formed on a substrate through a gate insulating film is shared by a coupling capacitor 308, a tunneling capacitor 326 and a read transistor 320. The coupling capacitor 308 is composed of the single-layer polygate 354 and an N-well 334 formed in the substrate. A P-type diffusion layer 310 and an N-type diffusion layer 318 are formed in the N-well 334 of the coupling capacitor 308. The P-type diffusion layer 310 and the N-type diffusion layer 318 are formed to be abutted to each other in the N-well 334. On the other hand, the tunneling capacitor 326 is composed of the single-layer polygate 354 and an N-well 334 formed in the substrate. A P-type diffusion layer 322 and an N-type diffusion layer 324 are formed in the N-well 334 of the tunneling capacitor 326. The P-type diffusion layer 322 and the N-type diffusion layer 324 are formed to be abutted to each other in the N-well 334, charges are injected into the floating gate 360 through the gate insulating film of the tunneling capacitor 326.

### SUMMARY OF THE INVENTION

The inventor of the present application has first recognized the following points. In FIG. 1, electrons injected into the floating gate 360 are supplied mainly from the N+ diffusion layers 324 of the tunneling capacitor 326. On the other hand, holes injected into the floating gate 360 are supplied mainly from the P+ diffusion layer 322 of the tunneling capacitor 326. However, as shown in FIG. 1, a contact width of the P+ diffusion layer 322 with respect to a tunneling region where charges are transferred is different from that of the N+diffusion layer 324. Accordingly, an efficiency of the hole supply at the time of programming is different from an efficiency of the electron supply at the time of erasing. Such an unbalance of the charge supply efficiency causes a difference between a time required for the programming and a time required for the erasing. One of the programming time and the erasing time becomes longer than the other of the programming time and the erasing time, which deteriorates programming/erasing characteristics of the EEPROM.

In an aspect of the present invention, an EEPROM having a nonvolatile memory cell is provided. The nonvolatile memory cell according to the present invention has: a first well formed in a substrate; and a floating gate formed on the substrate through a gate insulating film. The floating gate is so formed as to overlap a tunneling region in the first well. The floating gate and the first well form a tunneling capacitor, and charge injection and ejection with respect to the floating gate occur through the gate insulating film between the tunneling region and the floating gate. Moreover, a first diffusion layer and a second diffusion layer are so formed in the first well as to contact the tunneling region. The first diffusion layer and the second diffusion layer are of opposite conductivity types, and are provided such that efficiencies of the charge supply to the floating gate from respective of the first diffusion layer and the second diffusion layer are substantially equal to each other. For example, the first diffusion layer and the second diffusion layer are so formed as to contact the tunneling region over the same length.

In the EEPROM thus constructed, for example, the fist diffusion layer is an N+ diffusion layer as an electron supply source, while the second diffusion layer is a P+ diffusion layer as a hole supply source. Both of the N+ diffusion layer and the P+ diffusion layer as the supply sources are not located away from the tunneling region but provided to contact the tunneling region. Therefore, the supply efficiencies of holes/electrons at the time of programming/erasing are improved.

Furthermore, the contact width of the N+ diffusion layer with respect to the tunneling region is substantially equal to that of the P+ diffusion layer. As a result, an unbalance of the charge supply efficiency between in the programming and in the erasing is eliminated. In other words, a difference between the programming time and the erasing time is reduced. Since an extreme increase in the programming time or the erasing time is prevented, the programming/erasing characteristics of the EEPROM are improved. In a case where the P+ diffusion layer and the N+ diffusion layer are provided separately to face each other across the first region, it is possible to easily make the above-mentioned contact widths equal to each other, which is preferable from a viewpoint of manufacturing process.

According to the nonvolatile memory cell (EEPROM) of the present invention, the unbalance of the charge supply efficiency between in the programming and in the erasing is eliminated, and thus the difference between the programming time and the erasing time is reduced. Since an extreme increase in the programming time or the erasing time is prevented, the programming/erasing characteristics of the EEPROM are improved.

### BRIEF DESCRIPTION OF THE DRAWINGS

The above and other objects, advantages and features of the present invention will be more apparent from the following description taken in conjunction with the accompanying drawings, in which:

FIG. 1 is a plan view schematically showing a structure of a conventional single poly EEPROM;

FIG. 2 is a plan view showing a structure of a nonvolatile memory cell (EEPROM) according to a first embodiment of the present invention;

FIG. 3A is a cross-sectional view showing a structure along a line A-A′ in FIG. 2;

FIG. 3B is a cross-sectional view showing a structure along a line B-B′ in FIG. 2;

FIG. 3C is a cross-sectional view showing a structure along a line C-C′ in FIG. 2;

FIG. 3D is a cross-sectional view showing a structure along a line D-D′ in FIG. 2;

FIG. 4 is a plan view showing in detail a structure of a tunneling capacitor according to the present invention;

FIG. 5 is a plan view showing a modification example of the tunneling capacitor according to the present invention;

FIG. 6 is a schematic diagram showing a data erasing operation (ERASE) according to the first embodiment;

FIG. 7 is a schematic diagram showing a data programming operation (PROGRAM) according to the first embodiment;

FIG. 8 is a plan view showing a structure of a nonvolatile memory cell (EEPROM) according to a second embodiment of the present invention;

FIG. 9 is a schematic diagram showing a data programming operation (PROGRAM) according to the second embodiment;

FIG. 10 is a schematic diagram for explaining an effect of the second embodiment; and

FIG. 11 is a plan view showing a structure of a nonvolatile memory cell (EEPROM) according to a third embodiment of the present invention.

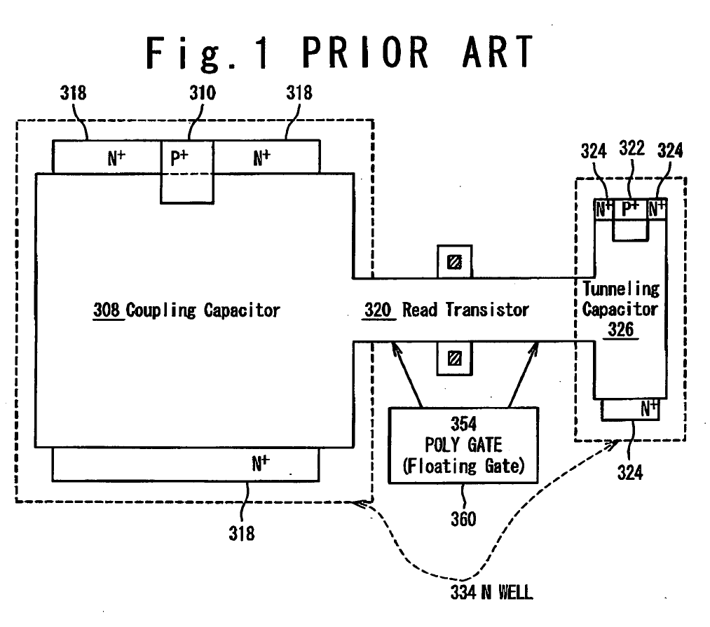

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

A nonvolatile memory according to embodiments of the present invention will be described below with reference to the attached drawings. The nonvolatile memory according to the embodiments is an EEPROM having a plurality of nonvolatile memory cells.

### 1. First Embodiment

1-1. Structure and Principle

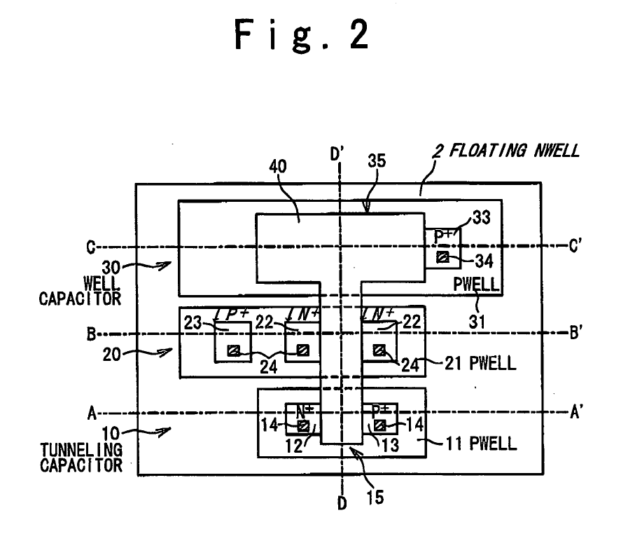

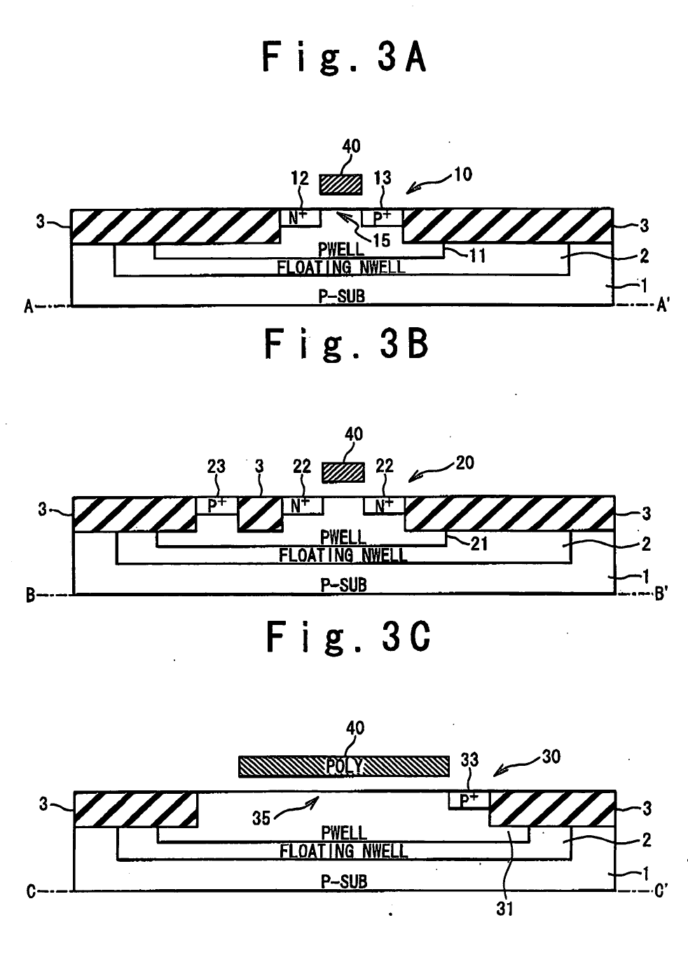

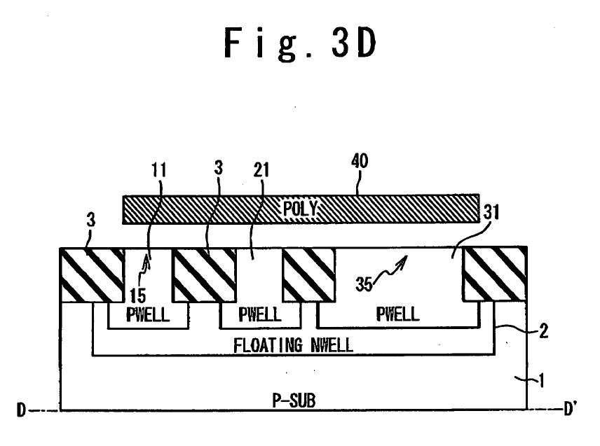

FIG. 2 is a plan view showing a structure of the nonvolatile memory cell (EEPROM) according to a first embodiment of the present invention. Cross-sectional structures along a line A-A′, a line B-B′, a line C-C′ and a line D-D′ in FIG. 2 are illustrated in FIG. 3A, FIG. 3B, FIG. 3C and FIG. 3D, respectively.

As shown in FIG. 2, the nonvolatile memory cell according to the present embodiment has a tunneling capacitor 10, a read transistor 20 and a well capacitor 30. Furthermore, a floating gate 40 is provided with respect to the tunneling capacitor 10, the read transistor 20 and the well capacitor 30.

Referring to FIG. 2, the tunneling capacitor 10 is constituted by a P-well 11 and the floating gate 40. A region in which the floating gate 40 overlaps the P-well 11 is hereinafter referred to as a “tunneling region 15”. An N+ diffusion layer 12 and a P+ diffusion layer 13 are so formed in the P-well 11 as to contact the tunneling region 15. Moreover, contacts 14 are formed to be connected to the N+ diffusion layer 12 and the P+ diffusion layer 13. FIG. 3A further shows the cross-sectional structure of the tunneling capacitor 10. A device isolation structure 3 is formed in a predetermined region of a surface portion of a P-type substrate 1. A floating N-well 2 is formed in the P-type substrate 1, and the P-well 11 is formed in the floating N-well 2. The floating gate 40 is formed on the P-well 11 through a gate insulating film. The region in which the floating gate 40 overlaps the P-well 11 is the above-mentioned tunneling region 15. In the P-well 11, the N+ diffusion layer 12 and the P+ diffusion layer 13 are formed to contact the tunneling region 15.

Referring to FIG. 2 again, the read transistor 20 is an N-channel MOS transistor formed on a P-well 21. More specifically, N+ diffusion layers 22 as source/drain and a P+ diffusion layer 23 for supplying a well potential are formed in the P-well 21. Contacts 24 are formed to be connected to the N+ diffusion layers 22 and the P+ diffusion layer 23. FIG. 3B further shows the cross-sectional structure of the read transistor 20. A device isolation structure 3 is formed in a predetermined region of a surface portion of the P-type substrate 1. A floating N-well 2 is formed in the P-type substrate 1, and the P-well 21 is formed in the floating N-well 2. The N+ diffusion layers (source/drain) 22 and the P+ diffusion layer 23 are formed in the P-well 21. The floating gate 40 is formed on a region sandwiched by the N+ diffusion layers 22 through a gate insulating film. That is, the read transistor 20 uses the floating gate 40 as a gate electrode.

Referring to FIG. 2 again, the well capacitor 30 is constituted by a P-well 31 and the floating gate 40. A region in which the floating gate 40 overlaps the P-well 31 is hereinafter referred to as an “overlap region 35”. A P+ diffusion layer 33 is formed in the P-well 31, and a contact 34 is formed to be connected to the P+ diffusion layer 33. FIG. 3C further shows the cross-sectional structure of the well capacitor 30. A device isolation structure 3 is formed in a predetermined region of a surface portion of the P-type substrate 1. A floating N-well 2 is formed in the P-type substrate 11 and the P-well 31 is formed in the floating N-well 2. The floating gate 40 is formed on the P-well 31 through a gate insulating film.

FIG. 3D shows the structure of the floating gate 40. The floating gate 40 is so formed as to extend over the P-well 11, the P-well 21 and the P-well 31. That is, the floating gate 40 is provided in common with respect to the tunneling capacitor 10, the read transistor 20 and the well capacitor 30. Preferably, as shown in FIG. 3D, the floating gate 40 has a single-layer structure. The single-layer floating gate 40 is formed of, for example, a single-layer polysilicon. The floating gate 40 is surrounded by an insulating film and electrically isolated from the surrounding circuitry.

The P-well 11 and the P-well 31 are capacitively coupled to the floating gate 40. In the present embodiment, the P-well 31 of the well capacitor 30 serves as a “control gate”. On the other hand, the charge injection and ejection with respect to the floating gate 40 occur through the gate insulating film (tunnel insulating film) between the tunneling region 15 of the P-well 11 and the floating gate 40.

The principle of the charge transfer with respect to the floating gate 40 is as follows. A first potential is applied to the N+ diffusion layer 12 and the P+ diffusion layer 13 of the tunneling capacitor 10 through the contacts 14 shown in FIG. 2. Also, a second potential is applied to the P+ diffusion layer 33 of the well capacitor 30 through the contact 34. The second potential is different from the first potential by a predetermined potential difference, and thus a potential corresponding to the predetermined potential difference is induced at the floating gate 40.

For example, a potential Ve is applied to the P+ diffusion layer 33 of the well capacitor 30, while a ground potential GND is applied to the N+ diffusion layer 12 and the P+ diffusion layer 13 of the tunneling capacitor 10. A capacitance (gate capacitance) between the P-well 11 of the tunneling capacitor 10 and the floating gate 40 is represented by C10, while a capacitance between the P-well 31 of the well capacitor 30 and the floating gate 40 is represented by C30. In this case, a potential Vg induced at the floating gate 40 due to the capacitive coupling is given by the following equation (1).

$$\begin{matrix}Vg = C 30 / ( C 30 + C 10 ) * Ve \\ = ( 1 / ( 1 + C 10 / C 30 ) ) * Ve\end{matrix} \qquad Eq . ( 1 )$$

In the equation (1), the parameter “C10/C30” is called a “capacitance ratio”. The potential difference (voltage) between the potential Vg of the floating gate 40 and the ground potential GND is applied to the gate insulating film in the tunneling region 15. The FN tunneling occurs due to a strong electric field corresponding to that voltage, and thereby charges are transferred through the gate insulating film in the tunneling region 15. A designer can set the capacitance ratio C10/C30 and the potential Ve such that the voltage Vg of a desired value is obtained. As the capacitance ratio C10/C30 is set smaller, the same voltage Vg can be obtained with a smaller potential Ve, namely the voltage Vg can be obtained efficiently. It is therefore preferable that an area of the tunneling region 15 is designed to be smaller than an area of the overlap region 35 (C10<C30), as shown in FIG. 2.

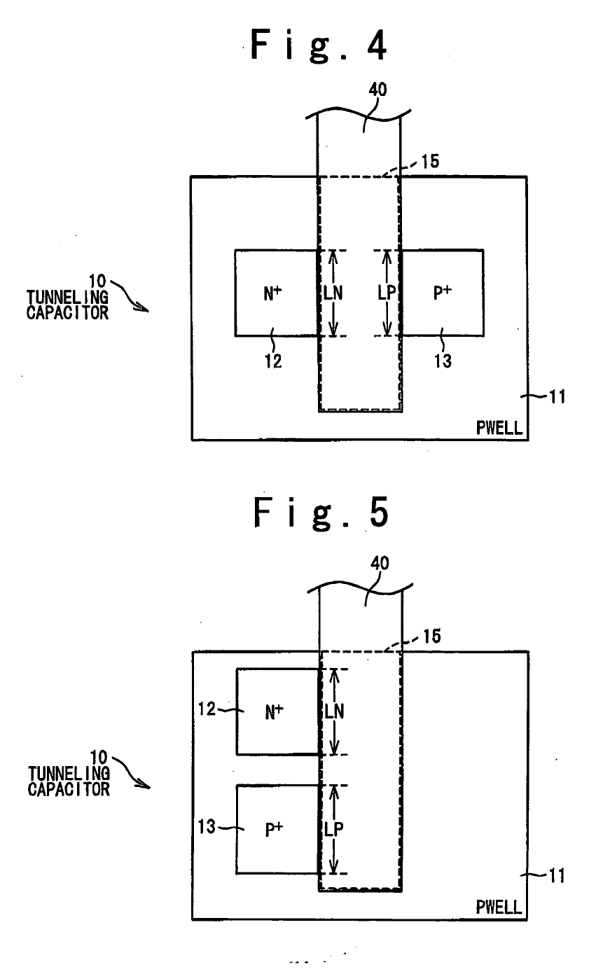

With regard to the charge transfer due to the FN tunneling, the N+ diffusion layer 12 of the tunneling capacitor 10 serves as an electron supply source, while the P+ diffusion layer 13 of the tunneling capacitor 10 serves as a hole supply source. An example of an arrangement of the N+ diffusion layer 12 and the P+ diffusion layer 13 is shown in FIG. 4. In FIG. 4, the N+ diffusion layer 12 and the P+ diffusion layer 13 are so formed as to contact the tunneling region 15. Moreover, the N+ diffusion layer 12 and the P+ diffusion layer 13 are independently formed to be separated from each other. Furthermore, the N+ diffusion layer 12 and the P+ diffusion layer 13 are so formed as to face each other across the tunneling region 15.

In addition, according to the present embodiment, the N+ diffusion layer 12 and the P+ diffusion layer 13 are designed such that efficiencies of the charge supply (charge transfer) to the floating gate 40 from respective of the N+ diffusion layer 12 and the P+ diffusion layer 13 are substantially equal to each other. More specifically, a width LN over which the N+ diffusion layer 12 contacts the tunneling region 15 is designed to be substantially equal to a width LP over which the P+ diffusion layer 13 contacts the tunneling region 15, as shown in FIG. 4. Since the contact width LN and the contact width LP are the same, the efficiency of the electron supply and the efficiency of the hole supply are balanced. In other words, an unbalance of the charge supply efficiency between in a programming operation and in an erasing operation is eliminated. Therefore, a difference between the programming time and the erasing time is reduced. Since an extreme increase in the programming time or the erasing time is prevented, programming/erasing characteristics of the EEPROM are improved.

When the N+ diffusion layer 12 and the P+ diffusion layer 13 contact the tunneling region 15 over the same length, the balance of the charge supply efficiency can be achieved. Therefore, the arrangement of the N+ diffusion layer 12 and the P+ diffusion layer 13 is not limited to that shown in FIG. 4. For example, as shown in FIG. 5, the N+ diffusion layer 12 and the P+ diffusion layer 13 may contact the same side of the tunneling region 15. Also in this case, the contact width LN is designed to be equal to the contact width LP. It should be noted that the N+ diffusion layer 12 and the P+diffusion layer 13 can be formed in a self-aligned manner in the case of the foregoing FIG. 4 where the N+ diffusion layer 12 and the P+ diffusion layer 13 are formed to face each other across the tunneling region 15. That is to say, in the case of the arrangement shown in FIG. 4, it is possible to easily make the contact width LN and the contact width LP equal to each other. Therefore, the arrangement shown in FIG. 4 is preferable from a viewpoint of manufacturing process.

In addition to the above-described programming/erasing operations, the read operation is as follows. To read data stored in the nonvolatile memory, the potential state of the floating gate 40 is detected. In order to detect the potential state of the floating gate 40, a transistor is necessary. In the present embodiment, the above-mentioned read transistor 20 is used for the reading. In this case, the tunneling capacitor 10 used for the programming/erasing operations and the read transistor 20 used for the reading operation are provided separately. Therefore, stress applied to the gate insulating film is dispersed and hence deterioration of the gate insulating film is suppressed, which is preferable.

1-2. Operations

Next, data programming/erasing/reading operations of the nonvolatile memory cell according to the present embodiment will be described more in detail.

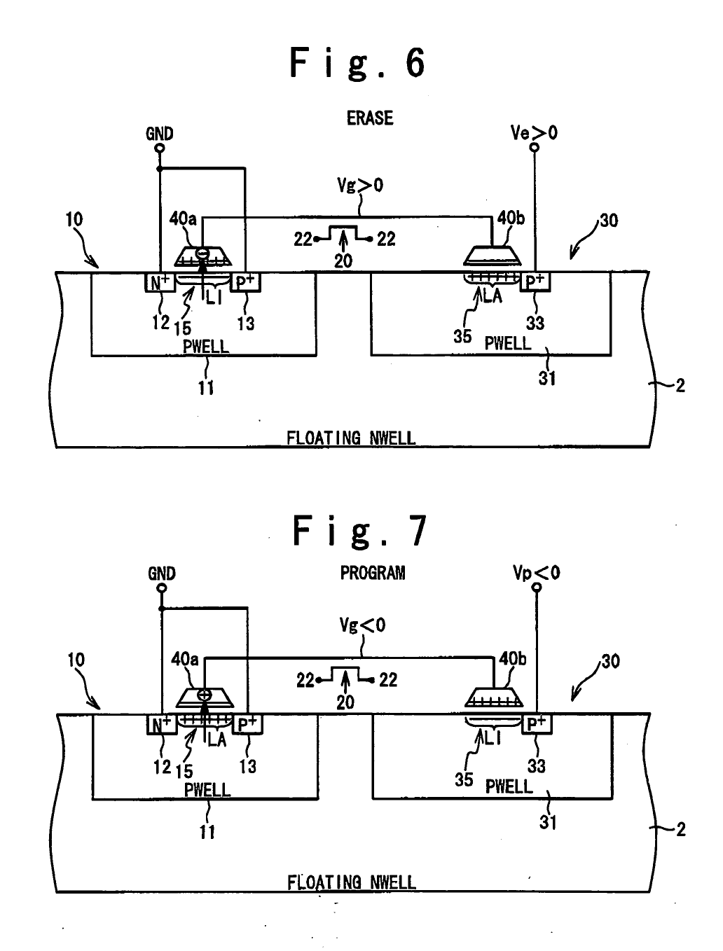

In the erasing operation, electrons are injected into the floating gate 40. FIG. 6 shows an example of a condition of the nonvolatile memory cell at the time of the erasing operation. In FIG. 6, the floating gate 40 is illustrated in such a manner that a gate electrode 40a of the tunneling capacitor 10 and a gate electrode 40b of the well capacitor 30 are distinguishable from each other. The gate electrode 40a and the gate electrode 40b are electrically connected to each other, and their potentials Vg are the same.

The potentials applied to the N+ diffusion layer 12, the P+ diffusion layer 13 and the P+ diffusion layer 33 can be designed appropriately. For example, as shown in FIG. 6, a positive erasing potential Ve is applied to the P+ diffusion layer 33 of the well capacitor 30. On the other hand, the ground potential GND is applied to the N+ diffusion layer 12 and the P+ diffusion layer 13 of the tunneling capacitor 10. As a result, a certain potential Vg is induced at the floating gate 40. In this case, a large number of electrons concentrate in a surface portion of the P-well 11 of the tunneling capacitor 10 to form an inversion layer LI. On the other hand, a large number of holes concentrate in a surface portion of the P-well 31 of the well capacitor 30 to form an accumulation layer LA. An electric field corresponding to the potential difference Vg is applied to the gate insulating film of the tunneling region 15, and thereby electrons are injected into the floating gate 40.

On the other hand, holes are injected into the floating gate 40 in the programming operation. FIG. 7 shows an example of a condition of the nonvolatile memory cell at the time of the programming operation in the same manner as in FIG. 6. The potentials applied to the N+ diffusion layer 12, the P+ diffusion layer 13 and the P+ diffusion layer 33 can be designed appropriately. For example, as shown in FIG. 7, a negative programming potential Vp is applied to the P+ diffusion layer 33 of the well capacitor 30. On the other hand, the ground potential GND is applied to the N+ diffusion layer 12 and the P+ diffusion layer 13 of the tunneling capacitor 10. As a result, a certain potential Vg is induced at the floating gate 40. In this case, a large number of holes concentrate in a surface portion of the P-well 11 of the tunneling capacitor 10 to form an accumulation layer LA. On the other hand, a large number of electrons concentrate in a surface portion of the P-well 31 of the well capacitor 30 to form an inversion layer LI. An electric field corresponding to the potential difference Vg is applied to the gate insulating film of the tunneling region 15, and thereby holes are injected into the floating gate 40.

In this manner, the electrons are injected into the floating gate 40 in the case of FIG. 6, while the holes are injected into the floating gate 40 in the case of FIG. 7. As described above, the N+ diffusion layer 12 as the electron supply source and the P+ diffusion layer 13 as the hole supply source contact the tunneling region 15 over substantially the same length. As a result, the charge supply efficiencies in the programming operation and in the erasing operation become substantially equal to each other. An unbalance of the charge supply efficiency between in the programming operation and in the erasing operation is eliminated, and a difference between the programming time and the erasing time is reduced. Since an extreme increase in the programming time or the erasing time is prevented, programming/erasing characteristics of the EEPROM are improved.

Data stored in the nonvolatile memory cell is read in accordance with a well known method by using the read transistor 20. That is to say, by detecting whether the read transistor 20 is turned ON or not, it is possible to sense a threshold voltage of the read transistor 20, namely, the potential state of the floating gate 40 corresponding to the stored data. According to the present embodiment, the read transistor 20 used for the read operation is provided separately from the capacitors 10 and 30. Therefore, stress applied to the gate insulating film is dispersed and hence deterioration of the gate insulating film is suppressed, which is preferable.

1-3. Effects

According to the present embodiment, the N+ diffusion layer 12 and the P+ diffusion layer 13 in the P-well 11 are so arranged as to contact the tunneling region 15. An effect obtained by such an arrangement is as follows. In the case of the EEPROM based on the FN tunneling current, the programming/erasing operations are generally performed by using a micro current of a few tens to a few hundreds of pA. It is therefore desirable in view of characteristics that resistance is designed to be as small as possible. If a well contact (P+ diffusion layer) is located away from the tunneling region 15, parasitic resistance of the well is added. According to the present embodiment, however, a well contact (P+ diffusion layer 13) is adjacent to the tunneling region 15. Therefore, the influence of the parasitic resistance of the well is prevented.

Moreover, according to the present embodiment, the N+ diffusion layer 12 functions as the electron supply source and the P+ diffusion layer 13 functions as the hole supply source. The N+ diffusion layer 12 and the P+ diffusion layer 13 are not located away from the tunneling region 15 but formed to contact the tunneling region 15. Therefore, the charge supply with respect to the tunneling region 15 in the programming/erasing operations becomes most efficient.

Furthermore, according to the present embodiment, the N+ diffusion layer 12 and the P+ diffusion layer 13 are designed such that the charge supply efficiencies to the floating gate 40 from respective of the N+ diffusion layer 12 and the P+ diffusion layer 13 are substantially equal to each other. Specifically, the contact width LN over which the N+ diffusion layer 12 contacts the tunneling region 15 is designed to be the substantially equal to the contact width LP over which the P+ diffusion layer 13 contacts the tunneling region 15. Since the contact width LN and the contact width LP are the same, the efficiency of the electron supply and the efficiency of the hole supply are balanced. In other words, an unbalance of the charge supply efficiency between in the programming operation and in the erasing operation is eliminated. Therefore, a difference between the programming time and the erasing time is reduced. Since an extreme increase in the programming time or the erasing time is prevented, programming/erasing characteristics of the EEPROM are improved.

### 2. Second Embodiment

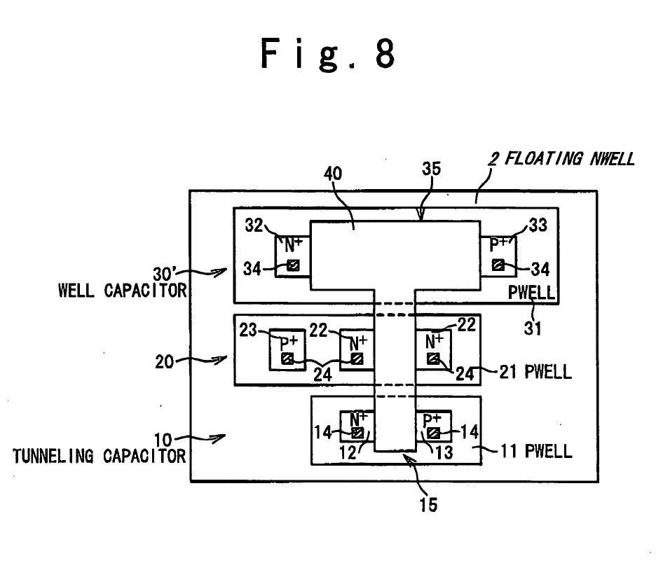

FIG. 8 is a plan view showing a structure of a nonvolatile memory cell (EEPROM) according to a second embodiment of the present invention. In FIG. 8, the same reference numerals are given to the same components as those described in the first embodiment, and a redundant description will be appropriately omitted. The nonvolatile memory cell according to the second embodiment has the tunneling capacitor 10, the read transistor 20 and a well capacitor 30′. The configuration of the tunneling capacitor 10 is the same as that in the first embodiment. Therefore, the same effects as those in the first embodiment can be obtained.

In the present embodiment, not only the P+ diffusion layer 33 but also an N+ diffusion layer 32 is formed in the P-well 31 of the well capacitor 30′. The N+ diffusion layer 32 and the P+ diffusion layer 33 are so formed as to contact the overlap region 35 where the floating gate 40 overlaps the P-well 31.

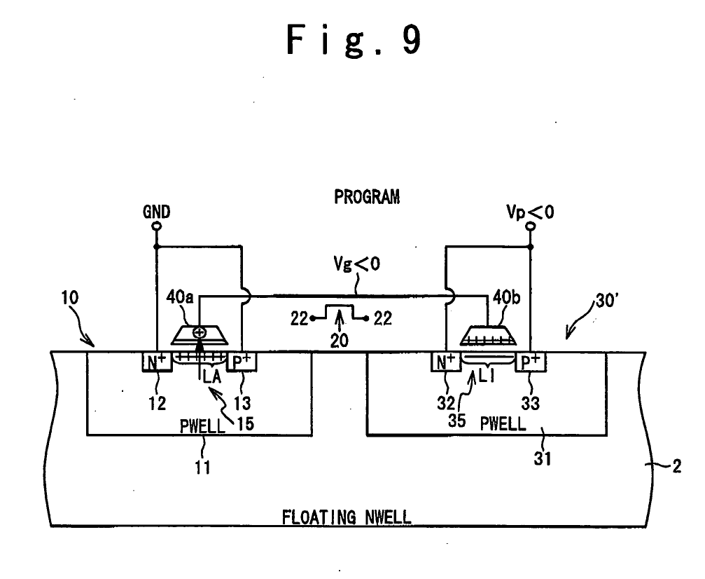

FIG. 9 is a view corresponding to FIG. 7 in the first embodiment and shows an example of a condition of the nonvolatile memory cell at the time of the programming operation. At the time of the programming operation, a negative programming potential Vp is applied to the N+ diffusion layer 32 and the P+ diffusion layer 33 of the well capacitor 30′. On the other hand, the ground potential GND is applied to the N+ diffusion layer 12 and the P+ diffusion layer 13 of the tunneling capacitor 10. As a result, a certain potential Vg is induced at the floating gate 40. In this case, a large number of electrons concentrate in a surface portion of the P-well 31 of the well capacitor 30′ to form an inversion layer LI like an N-type semiconductor. An electric field corresponding to the potential difference Vg is applied to the gate insulating film of the tunneling region 15, and thereby holes are injected into the floating gate 40.

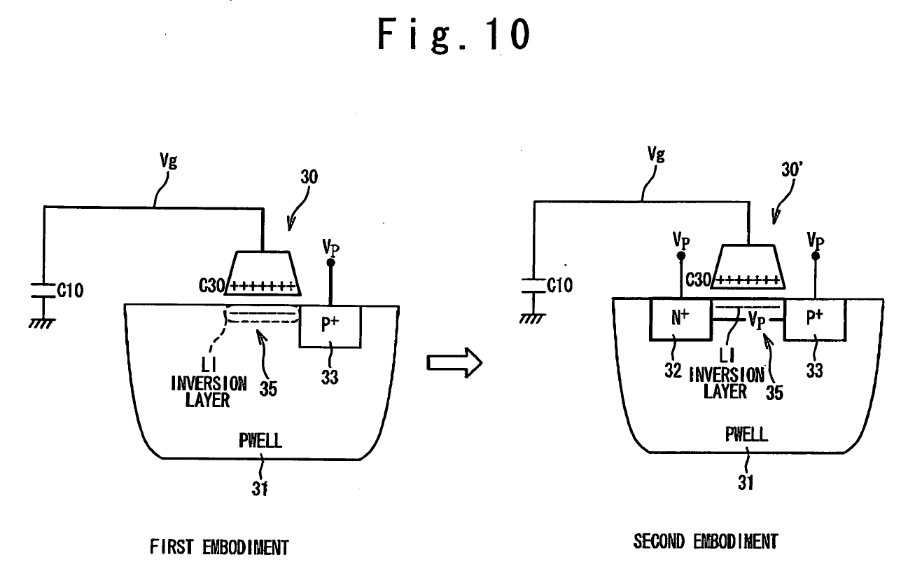

In order to explain an effect of the second embodiment, let us make a comparison between the condition shown in FIG. 7 (the first embodiment) and the condition shown in FIG. 9 (the second embodiment). The comparison is shown in FIG. 10. In FIG. 10, the gate capacitance of the tunneling capacitor 10 is represented by C10, while the gate capacitance of the well capacitor 30 (30′) is represented by C30. In this case, referring to the above-mentioned equation (1), the potential Vg of the floating gate 40 would be given by the following equation (2):
Vg=(1/(1+C10/C30))*Vp: Eq. (2)

In the case of the first embodiment, however, negative charges (−) of the inversion layer LI in the overlap region 35 causes change in the effective gate capacitance C30. As a result, the potential Vg induced at the floating gate 40 deviates from a desired value. This means that the potential difference Vg applied to the gate insulating film of the tunneling capacitor 10 deviates from a desired value (design value). The deviation of the potential difference Vg from the design value causes variation of the programming/erasing characteristics with respect to the memory cell and thus deteriorates reliability of the memory.

In the case of the second embodiment, on the other hand, the N+ diffusion layer 32 and the P+ diffusion layer 33 are formed in the P-well 31, and the programming potential Vp is applied to the N+ diffusion layer 32 and the P+ diffusion layer 33. In addition, the N+ diffusion layer 32 and the P+ diffusion layer 33 contact the overlap region 35. In this case, the inversion layer LI (N-type semiconductor) formed in the overlap region 35 is directly connected to the adjacent N+ diffusion layer 32, and thus both the layers are electrically connected with each other. As a result, the potential of the inversion layer LI is fixed at the programming potential Vp. Since the potential of the inversion layer LI is fixed, the variation of the effective gate capacitance C30 due to the negative charges (−) of the inversion layer LI is prevented.

It should be noted that the case of the inversion layer LI is described in FIG. 10 and the same applies to a case of an accumulation layer LA. In a case where an accumulation layer LA is formed in the overlap region 35, the accumulation layer LA is electrically connected to the adjacent P+ diffusion layer 33. As a result, the potential of the accumulation layer LA is fixed at a predetermined potential. Since the potential of the accumulation layer LA is fixed, the variation of the effective gate capacitance C30 due to the positive charges (+) of the accumulation layer LA is prevented. The reason why both the N+ diffusion layer 32 and the P+ diffusion layer 33 are provided in the P-well 31 is to support both the case of the inversion layer LI and the case of the accumulation layer LA.

According to the present embodiment, as described above, the N+ diffusion layer 32 and the P+ diffusion layer 33 of the opposite conductivity types are so provided as to contact the overlap region 35 of the well capacitor 30′. Therefore, whether the accumulation layer LA is formed in the overlap region 35 or the inversion layer LI is formed in the overlap region 35, the potential of the accumulation layer LA or the inversion layer LI is fixed at a predetermined potential. As a result, it is prevented that the effective gate capacitance C30 varies due to the positive charges (+) of the accumulation layer LA or the negative charges (−) of the inversion layer LI. Therefore, the deviation of the potential difference Vg applied to the gate insulating film of the tunneling region 15 from the design value is prevented. Since the potential difference equal to the design value is generated, the variation of the programming/erasing characteristics with respect to the memory cell is prevented and thereby reliability of the memory is improved.

It should be noted that the N+ diffusion layer 12 and the P+ diffusion layer 13 contact the tunneling region 15 of the tunneling capacitor 10 in both the first and the second embodiments. Therefore, variation of the effective gate capacitance C10 of the tunneling capacitor 10 is prevented in both the first and the second embodiments. It can be said that not only the variation of the gate capacitance C10 of the tunneling capacitor 10 but also the variation of the gate capacitance C30 of the well capacitor 30 is prevented according to the second embodiment.

### 3. Third Embodiment

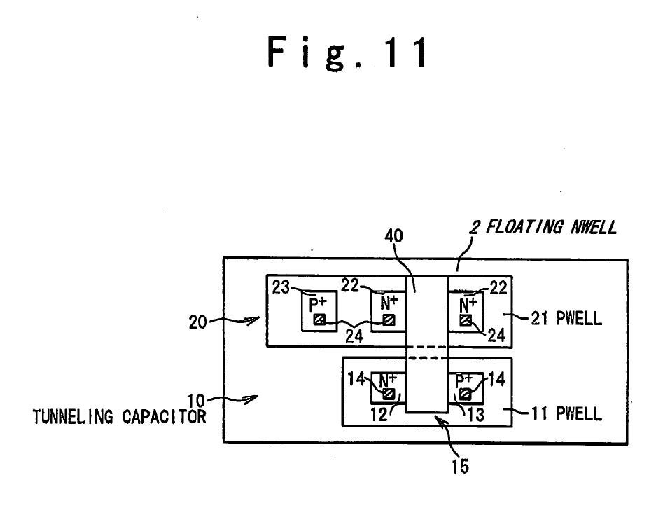

FIG. 11 is a plan view showing a structure of a nonvolatile memory cell (EEPROM) according to a third embodiment of the present invention. In FIG. 11, the same reference numerals are given to the same components as those described in the first embodiment, and a redundant description will be appropriately omitted. The nonvolatile memory cell according to the third embodiment has two elements of the tunneling capacitor 10 and the read transistor 20. As compared with the foregoing embodiments, the well capacitor 30 is omitted.

In the present embodiment, the read transistor 20 serves as the well capacitor 30 in the first embodiment. That is to say, the read transistor 20 is used not only in the read operation but also in the programming/erasing operations. In the programming/erasing operations, a first potential is applied to the N+ diffusion layer 12 and the P+ diffusion layer 13 of the tunneling capacitor 10. Furthermore, a second potential is applied to the source/drain 22 and the P-well 21 of the read transistor 20 through the contacts 24. The second potential is different from the first potential by a predetermined potential difference, and thus a potential corresponding to the predetermined potential difference is induced at the floating gate 40. Then, charges are injected into of ejected from the floating gate 40 through the gate insulating film of the tunneling region 15.

The configuration of the tunneling capacitor 10 is the same as that in the first embodiment. Therefore, the same effects as those in the first embodiment can be obtained. Moreover, according the third embodiment, an additional effect that a memory cell area is reduced can be obtained as compared with the case of the three elements structure in the foregoing embodiments.

It is apparent that the present invention is not limited to the above embodiment and may be modified and changed without departing from the scope and spirit of the invention.

What is claimed is:

1. An EEPROM having a nonvolatile memory cell, said nonvolatile memory cell comprising:
a first well formed in a substrate;
a floating gate formed on said substrate through a gate insulating film to overlap a first region of said first well; and
first and second diffusion layers formed in said first well to contact said first region,
wherein charge injection and ejection with respect to said floating gate occur through said gate insulating film between said first region and said floating gate,
wherein said first diffusion layer and said second diffusion layer are of opposite conductivity types and contact said first region over a same length.

2. The EEPROM according to claim 1,
wherein said first diffusion layer and said second diffusion layer are formed to be separated from each other.

3. The EEPROM according to claim 2,
wherein said first diffusion layer and said second diffusion layer are formed to face each other across said first region.

4. The EEPROM according to claim 1,
wherein said nonvolatile memory cell further comprises a transistor whose gate electrode is said floating gate,
wherein in data reading, a potential state of said floating gate is detected by using said transistor.

5. The EEPROM according to claim 4,
wherein in data programming and erasing, a first potential is applied to said first well, and a second potential different from said first potential by a predetermined potential difference is applied to a diffusion layer of said transistor.

6. The EEPROM according to claim 1,
wherein said nonvolatile memory cell further comprises a second well formed in said substrate and capacitively coupled to said floating gate,
wherein in data programming and erasing, a first potential is applied to said first well, and a second potential different from said first potential by a predetermined potential difference is applied to said second well.

7. The EEPROM according to claim 6,
wherein a capacitance between said second well and said floating gate is larger than a capacitance between said first well and said floating gate.

8. The EEPROM according to claim 6,
wherein said nonvolatile memory cell further comprises third and fourth diffusion layers formed in said second well,
wherein said floating gate overlaps a second region of said second well, said third diffusion layer and said fourth diffusion layer are of opposite conductivity types and are formed to contact said second region.

9. The EEPROM according to claim 1,
wherein said floating gate is formed of a single-layer polysilicon.

10. An EEPROM having a nonvolatile memory cell, said nonvolatile memory cell comprising:
a first well formed in a substrate;
a floating gate formed on said substrate through a gate insulating film to overlap a first region of said first well; and
first and second diffusion layers formed in said first well to contact said first region,
wherein charge supply to said floating gate is performed through said gate insulating film between said first region and said floating gate,
wherein said first diffusion layer and said second diffusion layer are of opposite conductivity types and are provided such that efficiencies of said charge supply to said floating gate from respective of said first diffusion layer and said second diffusion layer are equal to each other.

11. An EEPROM having a nonvolatile memory cell, said nonvolatile memory cell comprising:
a first well formed in a substrate;
a floating gate formed on said substrate through a gate insulating film to overlap a first region of said first well; and
first and second diffusion layers formed in said first well to contact said first region,
wherein charge injection and ejection with respect to said floating gate occur through said gate insulating film between said first region and said floating gate,
wherein said first diffusion layer and said second diffusion layer are of opposite conductivity types and are formed to be separated from each other.
